(19) United States
(12) Patent Application Publication
(10) Pub. No.: US 2024/0251552 A1
(43) Pub. Date: Jul. 25, 2024

(54) NAND STAIRCASE LANDING PADS CONVERSION

(71) Applicant: Micron Technology, Inc., Boise, ID (US)

(72) Inventors: Mojtaba Asadirad, Boise, ID (US); Yiping Wang, Boise, ID (US); David H. Wells, Boise, ID (US); Matt J. King, Boise, ID (US)

(21) Appl. No.: 18/417,709

(22) Filed: Jan. 19, 2024

Related U.S. Application Data
(60) Provisional application No. 63/441,127, filed on Jan. 25, 2023.

(51) Int. Cl. H10B 43/27; H10B 41/27

(52) U.S. Cl. CPC H10B 43/27; H10B 41/27

(57) ABSTRACT

Methods, systems, and devices for NAND staircase landing pads conversion are described. A memory device may include one or more lateral word line contacts that may couple a word line with a conductive pillar that traverses a stack of materials of the memory device. The use of the lateral word line contact may allow for a conductive pillar to be coupled with a target word line without requiring an end of the conductive pillar to be placed directly on the word line. Additionally, the memory architecture described herein may allow for the target word line to be coupled with CMOS circuitry via a first conductive pillar without the use of a second conductive pillar, as the first conductive pillar may traverse the stack of materials and be coupled with the CMOS circuitry. Therefore, total quantity of conductive pillars may be reduced, and the risk of manufacturing errors may be lowered.

### CROSS REFERENCE

The present Application for Patent claims priority to and the benefit of U.S. Provisional Application No. 63/441,127 by Asadirad et al., entitled “NAND STAIRCASE LANDING PADS CONVERSION,” filed Jan. 25, 2023, assigned to the assignee hereof, and which is expressly incorporated by reference in its entirety herein.

### TECHNICAL FIELD

The following relates to one or more systems for memory, including replacement gate not-and (NAND) staircase tier landing pads conversion.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 illustrates an example of a system that supports NAND staircase landing pads conversion in accordance with examples as disclosed herein.

FIG. 2 illustrates an example of a memory architecture that supports NAND staircase landing pads conversion in accordance with examples as disclosed herein.

FIGS. 3A through 3I illustrate examples of structures that support NAND staircase landing pads conversion in accordance with examples as disclosed herein.

FIG. 4 illustrates a block diagram of a memory system that supports NAND staircase landing pads conversion in accordance with examples as disclosed herein.

### DETAILED DESCRIPTION

Some memory devices may include a staircase region. That is, a memory device may include a region in which a quantity of layers (e.g., conductive layers or word lines) of the memory device progressively decreases, forming a staircase structure. The staircase region may be configured to allow different pillars to couple with different layers of the memory device. In some examples, the memory device may include multiple conductive pillars that may couple respective conductive layers (e.g., word lines) with complementary metal oxide semiconductor (CMOS) circuitry of the memory device (e.g., one or more transistors). For example, memory devices may include a first conductive pillar, where one end of the first conductive pillar is in contact with a target word line, and another end of the first conductive pillar is coupled with a second conductive pillar that traverses a stack of materials of the memory device and couples to the CMOS circuitry.

To improve the capacity of memory devices, the layers of the memory devices may become smaller (e.g., thinner) to allow for a larger quantity of layers (e.g., and word lines or memory cells). As the layers become smaller, however, coupling (e.g., landing) the first conductive pillar on a target word line may become more difficult. For example, errors could occur during production of the memory devices, and the first conductive pillar may fail to couple with the target word line, may couple with a non-targeted word line, or may couple the target word line with other word lines. These errors may cause a shorting of two or more word lines of the memory devices or create an open circuit at a word line, resulting in defective memory devices.

Accordingly, the present disclosure provides memory architectures and manufacturing methods that may decrease the risk for word line short circuits or open circuits at a memory device. In accordance with examples as described herein, a memory device may include one or more rivets (e.g., rivet contacts, lateral word line contacts) that may couple a word line with a conductive pillar that traverses a stack of materials of the memory device. The use of the rivet may allow for a conductive pillar to be coupled with a target word line without requiring an end of the conductive pillar to be placed (e.g., landed) directly on the word line. The manufacturing methods described herein may thereby ensure that the conductive pillar is coupled with a target word line and isolated from other word lines. Additionally, the memory architecture described herein may allow for the target word line to be coupled with CMOS circuitry via a first conductive pillar without the use of a second conductive pillar, as the first conductive pillar may traverse the stack of materials and be coupled with the CMOS circuitry. Therefore, total quantity of conductive pillars in the memory device may be reduced, and the risk of manufacturing errors may also be lowered.

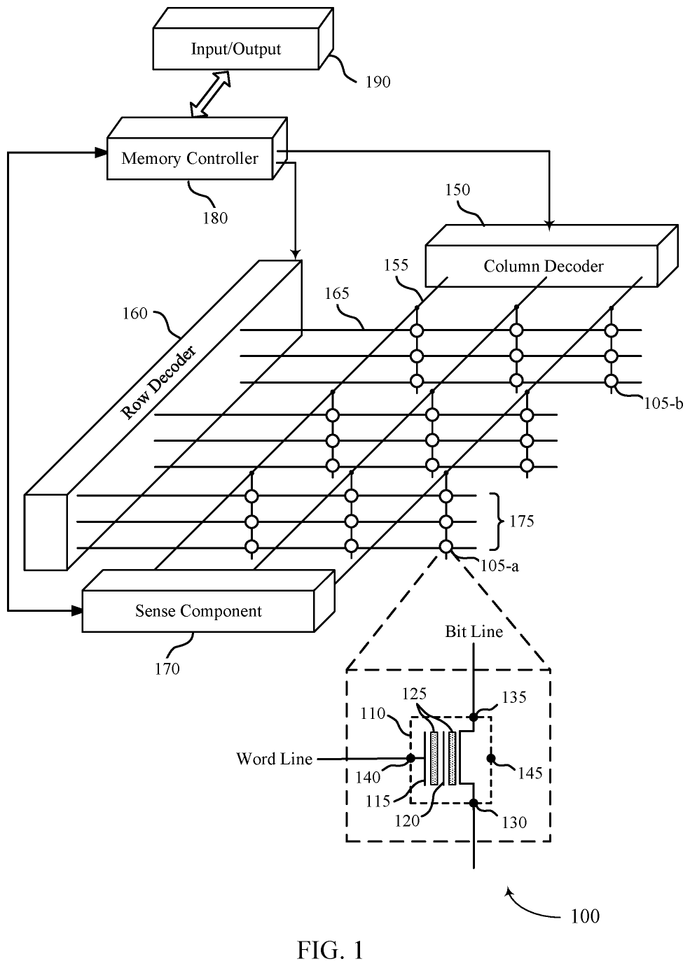

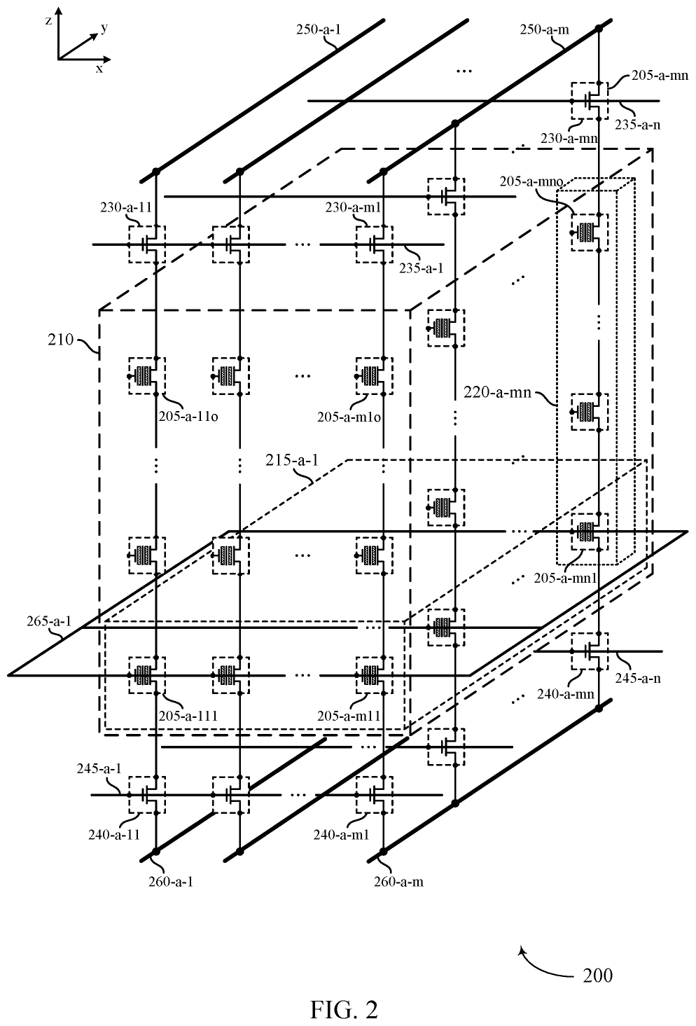

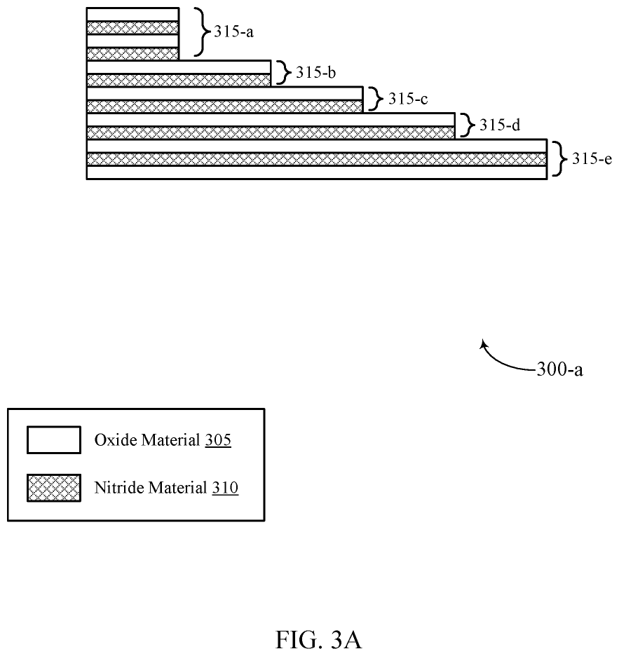

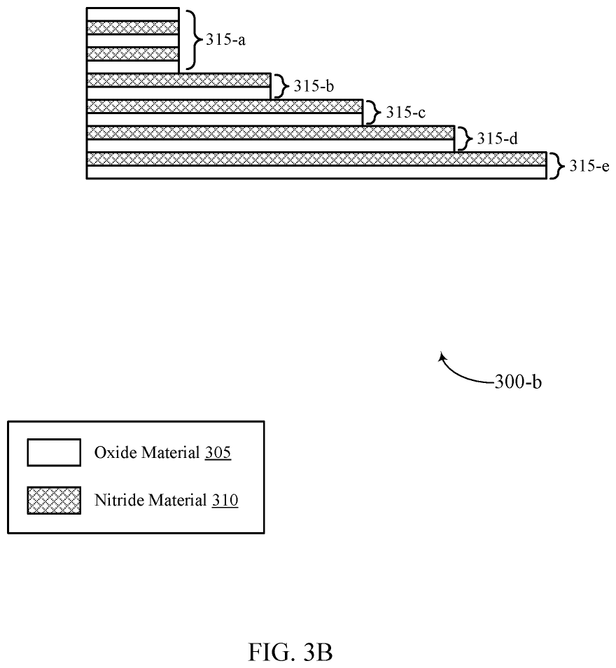

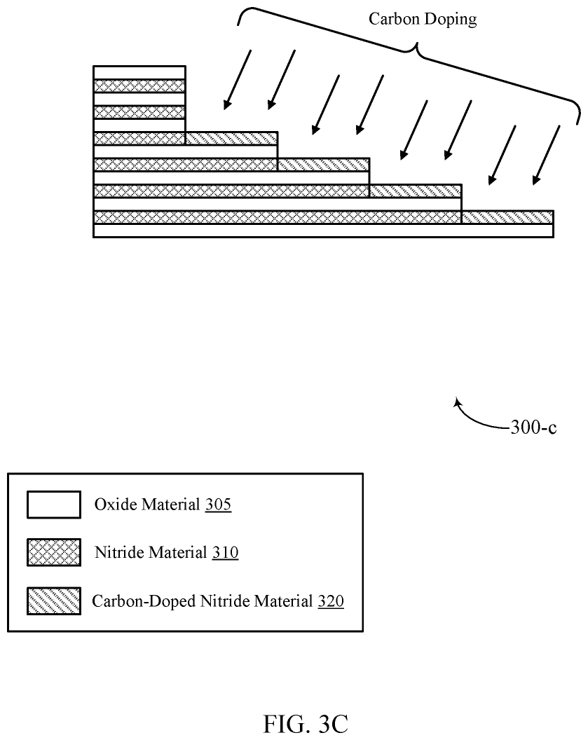

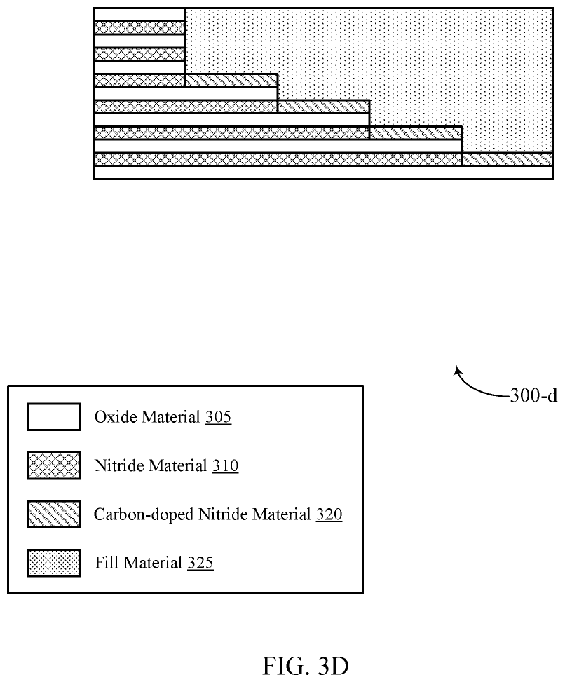

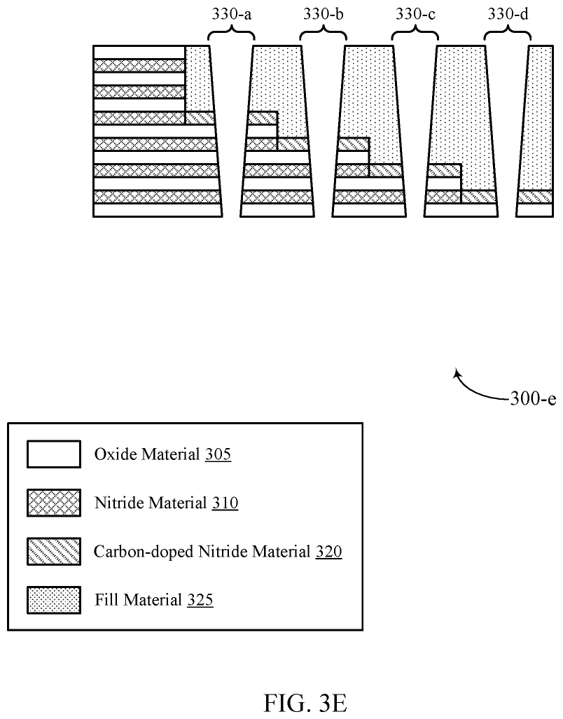

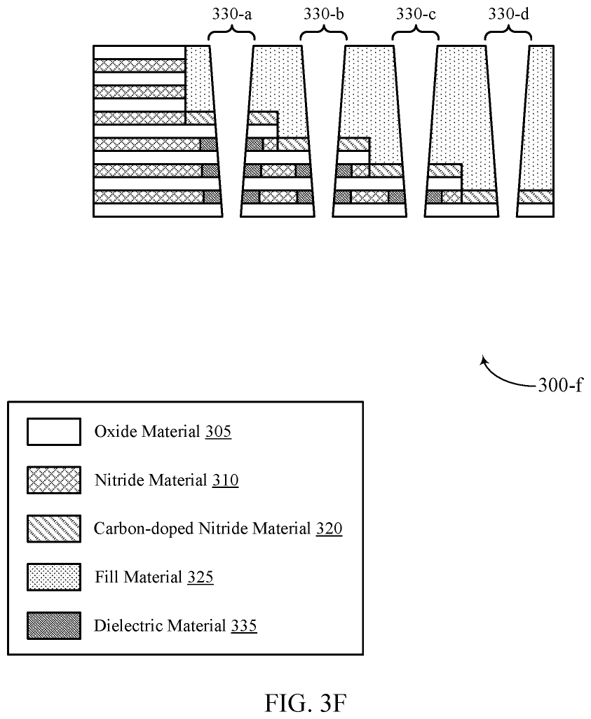

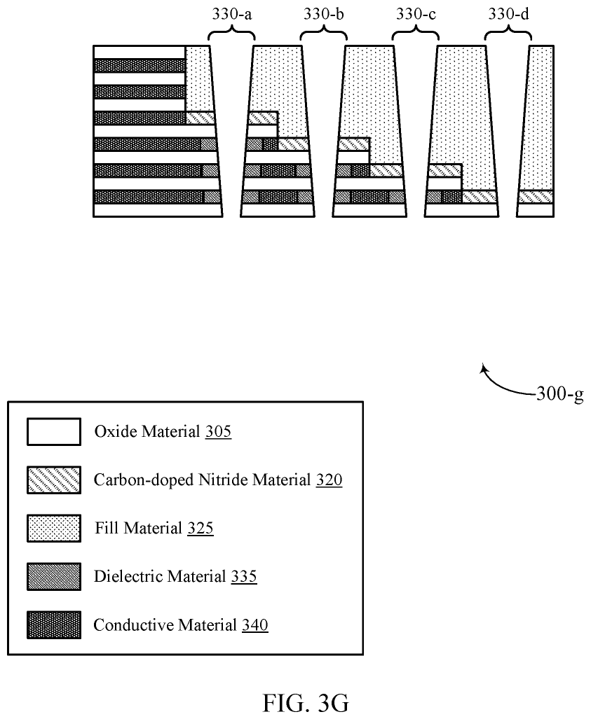

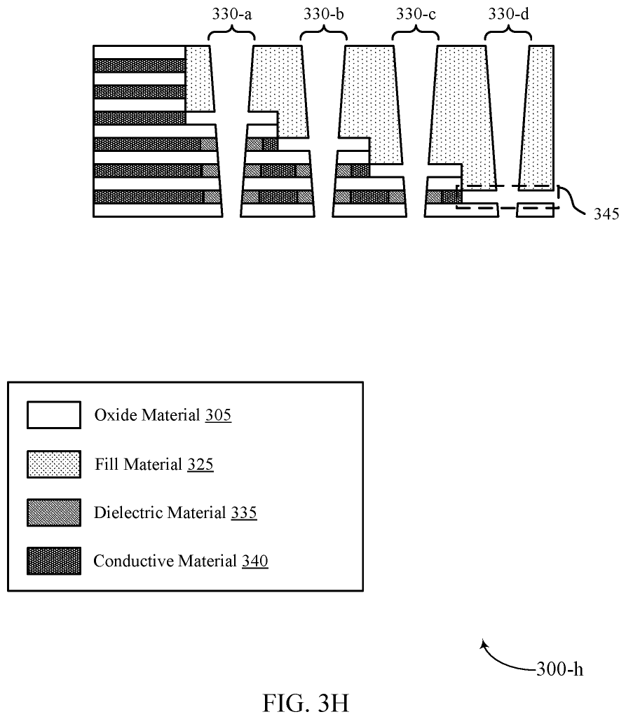

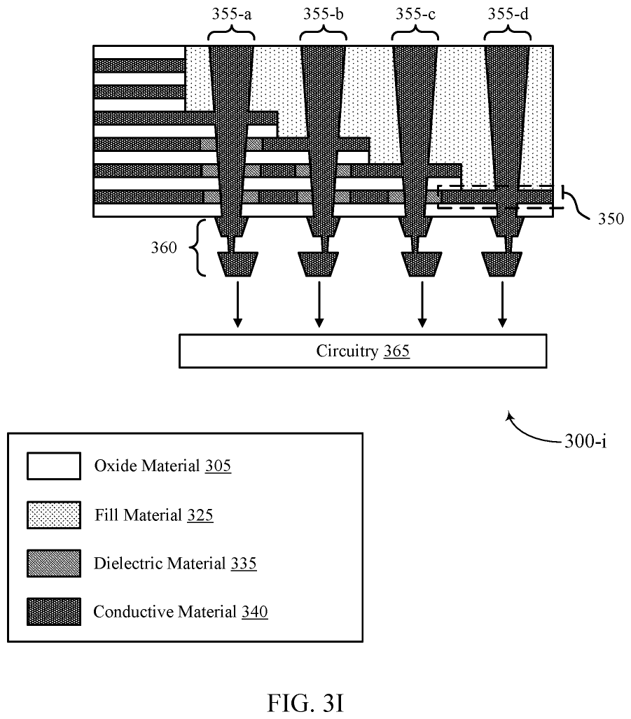

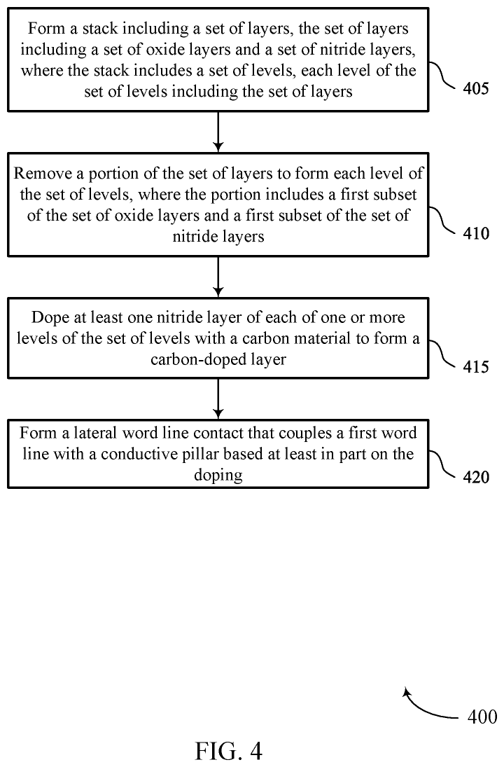

Features of the disclosure are initially described in the context of systems, devices, and circuits with reference to FIGS. 1 and 2. Features of the disclosure are described in the context of structures illustrating a manufacturing process with reference to FIGS. 3A through 3I. These and other features of the disclosure are further illustrated by and described in the context of a block diagram that relates to NAND staircase landing pads conversion with reference to FIG. 4.

FIG. 1 illustrates an example of a memory device 100 that supports NAND staircase landing pads conversion in accordance with examples as disclosed herein. FIG. 1 is an illustrative representation of various components and features of the memory device 100. As such, the components and features of the memory device 100 are shown to illustrate functional interrelationships, and not necessarily physical positions within the memory device 100. Further, although some elements included in FIG. 1 are labeled with a numeric indicator, some other corresponding elements are not labeled, even though they are the same or would be understood to be similar, in an effort to increase visibility and clarity of the depicted features.

The memory device 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as a multi-level cell (MLC), a tri-level cell (TLC), a quad-level cell (QLC), or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate that may be part of a 2D NAND structure. For example, a 2D NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., based on a presence or absence of a current through the memory cell 105 when a read voltage is applied to the control gate 115, based on whether the current is above or below a threshold current). For a multiple-level memory cell 105, a sense component 170 may determine a logic value stored in the memory cell 105 based on various intermediate threshold levels of current when a read voltage is applied to the control gate 115, or by applying different read voltages to the control gate and evaluating different resulting levels of current through the transistor 110, or various combinations thereof. In one example of a multiple-level architecture, a sense component 170 may determine the logic value of a TLC memory cell 105 based on eight different levels of current, or ranges of current, that define the eight potential logic values that could be stored by the TLC memory cell 105.

An SLC memory cell 105 may be written by applying one of two voltages (e.g., a voltage above a threshold or a voltage below a threshold) to memory cell 105 to store, or not store, an electric charge on the charge trapping structure 120 and thereby cause the memory cell 105 store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may in some cases, be considered as storing a logic 0. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. Removal of electrons from the charge trapping structure 120 may be referred to as erasing the memory cell 105 and may occur as part of an erase operation. An erased memory cell may in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In contrast to writing an SLC memory cell 105, writing a multiple-level (e.g., MLC, TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120, or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. The intersection may be referred to as an address of a memory cell 105. In some cases, word lines 165 and bit lines 155 may be substantially perpendicular to one another, and may be generically referred to as access lines or select lines.

In some cases, a memory device 100 may include a three-dimensional (3D) memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, memory device 100 includes multiple levels (e.g., decks, layers, planes, tiers) of memory cells 105. The levels may in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 may be referred to as a string of memory cells 105 (e.g., as described with reference to FIG. 2).

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of memory device 100.

To improve capacity of memory devices 100, the layers of the memory device 100 may become smaller to allow for a larger quantity of word lines 165, for example. As the layers become smaller, however, the distance between word lines 165 may also decrease. This may make coupling (e.g., landing) a first conductive pillar of the memory device 100 on a target word line 165 to couple the target word line 165 with circuitry (e.g., CMOS circuitry) of the memory device 100 more difficult. For example, errors could occur during production of the memory device 100, and the first conductive pillar may fail to reach the target word line 165 or may couple the target word line 165 with other word lines 165. These errors may cause a shorting two or more word lines 165 of the memory device 100 or create an open circuit at a word line 165, resulting in a defective memory device 100.

Accordingly, the disclosure provides architectures and manufacturing methods that may decrease the risk for word line short circuits or open circuits at a memory device 100. In accordance with examples as described herein, the memory device 100 may include one or more rivets (e.g., rivet contacts, lateral word line contacts) that may couple a word line 165 with a conductive pillar that traverses a stack of materials of the memory device 100. The use of the rivet may allow for a conductive pillar to be coupled with a target word line 165 without requiring an end of the conductive pillar to be placed (e.g., landed) directly on the word line 165. Thus, the manufacturing methods described herein may ensure the conductive pillar is coupled with a target word line 165 and isolated from other word lines 165. Additionally, the architecture described herein may allow for the target word line 165 to be coupled with CMOS circuitry via a first conductive pillar without the use of a second conductive pillar, as the first conductive pillar may both traverse the stack of materials and be coupled with the CMOS circuitry. Therefore, total quantity of conductive pillars in the memory device 100 may be reduced, and the risk of manufacturing errors may also be lowered.

FIG. 2 illustrates an example of a memory architecture 200 that supports NAND staircase landing pads conversion in accordance with examples as disclosed herein. The memory architecture 200 may be an example of a portion of a memory device, such as a memory device 100. Although some elements of a set of elements (e.g., an array of elements) are included in FIG. 2, some elements may be omitted for the sake of visibility and clarity of the depicted elements. Moreover, although some elements included in FIG. 2 are labeled with reference numbers, some other corresponding elements are not labeled, though they are the same or would be understood by a person having ordinary skill in the art to be similar. Aspects of the memory architecture 200 may be described with reference to an x-direction, a y-direction, and a z-direction of the illustrated coordinate system.

The memory architecture 200 includes a three-dimensional array of memory cells 205, which may be examples of memory cells 105 described with reference to FIG. 1 (e.g., transistors 110, NAND memory cells). In some examples, the memory cells 205 may be connected in a 3D NAND configuration. For example, the memory cells 205 may be included in a block 210, which may be arranged as a 3D array of m memory cells along the x-direction, n memory cells along the y-direction, and o memory cells along the z-direction. Each memory cell 205 may be located (e.g., addressed) in accordance with an index i along the x-direction, an index j along the y-direction, and an index k along the z-direction (e.g., for locating a memory cell 205-a-ijk). A memory device 100 may include any quantity of one or more blocks 210 in accordance with examples as disclosed herein, and different blocks 210 may be adjacent along the x-direction, along the y-direction, or along the z-direction, or any combination thereof.

In the example of memory architecture 200, the block 210 may be divided into a set of pages 215 (e.g., a quantity of o pages 215) along the z-direction, including a page 215-a-1 associated with memory cells 205-a-111 through 205-a-mn1. In some examples, each page 215 may be associated with a same word line 265, (e.g., a word line 165 described with reference to FIG. 1), which may be coupled with a control gate 115 of each of the memory cells 205 of the page 215. For example, page 215-a-1 may be associated with a word line 265-a-1, and other pages 215-a-i may be associated with a different respective word line 265-a-i (not shown). In some examples, a word line 265 in accordance with the memory architecture 200 may be implemented as planar conductor (e.g., in an xy-plane) that is coupled with each of the memory cells 205 of the page 215.

In the example of memory architecture 200, the block 210 also may be divided into a set of strings 220 (e.g., a quantity of (m×n) strings 220) in an xy-plane, including a string 220-a-mn associated with memory cells 205-a-mn1 through 205-a-mno. In some examples, each string 220 may include a set of memory cells 205 connected in series (e.g., along the z-direction, in which a drain of one memory cell 205 in the string 220 may be coupled with a source of another memory cell 205 in the string 220). In some examples, memory cells 205 of a string 220 may be implemented along a common channel, such as a pillar channel (e.g., a columnar channel, a pillar of doped semiconductor) along the z-direction. Each memory cell 205 in a string 220 may be associated with a different word line 265, such that a quantity of word lines 265 in the memory architecture 200 may be equal to the quantity of memory cells 205 in a string 220. Accordingly, a string 220 may include memory cells 205 from multiple pages 215, and a page 215 may include memory cells 205 from multiple strings 220.

In some examples, memory cells 205 may be programmed (e.g., set to a logic 0 value) and read from in accordance with a granularity, such as at the granularity of the page 215, but may not be erasable (e.g., reset to a logic 1 value) in accordance with the granularity, such as the granularity of the page 215. For example, NAND memory may instead be erasable in accordance with a different (e.g., higher) level of granularity, such as at the level of granularity the block 210. In some cases, a memory cell 205 may be erased before it may be re-programmed. Different memory devices may have different read, write, or erase characteristics.

In some examples, each string 220 of a block 210 may be coupled with a respective transistor 230 (e.g., a string select transistor, a drain select transistor) at one end of the string 220 (e.g., along the z-direction) and a respective transistor 240 (e.g., a source select transistor, a ground select transistor) at the other end of the string 220. In some examples, a drain of each transistor 230 may be coupled with a bit line 250 of a set of bit lines 250 associated with the block 210, where the bit lines 250 may be examples of bit lines 155 described with reference to FIG. 1. A gate of each transistor 230 may be coupled with a select line 235 (e.g., a string select line, a drain select line). Thus, a transistor 230 may be used to couple a string 220 with a bit line 250 based on applying a voltage to the select line 235, and thus to the gate of the transistor 230. Although illustrated as separate lines along the x-direction, in some examples, select lines 235 may be common to all the transistors 230 associated with the block 210 (e.g., a commonly biased string select node). For example, like the word lines 265 of the block 210, select lines 235 associated with the block 210 may in some examples, be implemented as a planar conductor (e.g., in an xy-plane) that is coupled with each of the transistors 230 associated with the block 210.

In some examples, a source of each transistor 240 associated with the block 210 may be coupled with a source line 260 of a set of source lines 260 associated with the block 210. In some examples, the set of source lines 260 may be associated with a common source node (e.g., a ground node) corresponding to the block 210. A gate of each transistor 240 may be coupled with a select line 245 (e.g., a source select line, a ground select line). Thus, a transistor 240 may be used to couple a string 220 with a source line 260 based on applying a voltage to the select line 245, and thus to the gate of the transistor 240. Although illustrated as separate lines along the x-direction, in some examples, select lines 245 also may be common to all the transistors 240 associated with the block 210 (e.g., a commonly biased ground select node). For example, like the word lines 265 of the block 210, select lines 245 associated with the block 210 may in some examples, be implemented as a planar conductor (e.g., in an xy-plane) that is coupled with each of the transistors 240 associated with the block 210.

To operate the memory architecture 200 (e.g., to perform a program operation, a read operation, or an erase operation on one or more memory cells 205 of the block 210), various voltages may be applied to one or more select lines 235 (e.g., to the gate of the transistors 230), to one or more bit lines 250 (e.g., to the drain of one or more transistors 230), to one or more word lines 265, to one or more select lines 245 (e.g., to the gate of the transistors 240), to one or more source lines 260 (e.g., to the source of the transistors 240), or to a bulk for the memory cells 205 (not shown) of the block 210. In some cases, each memory cell 205 of a block 210 may have a common bulk, the voltage of which may be controlled independently of bulks for other blocks 210.

In some cases, as part of a read operation for a memory cell 205, a positive voltage may be applied to the corresponding bit line 250 while the corresponding source line 260 may be grounded or otherwise biased at a voltage lower than the voltage applied to the bit line 250. In some examples, voltages may be concurrently applied to the select line 235 and the select line 245 that are above the threshold voltages of the transistor 230 and the transistor 240, respectively, for the memory cell 205, thereby activating the transistor 230 and transistor 240 such that a channel associated with the string 220 that includes the memory cell 205 (e.g., a pillar channel) may be electrically connected with (e.g., electrically connected between) the corresponding bit line 250 and source line 260. A channel may be an electrical path through the memory cells 205 in the string 220 (e.g., through the sources and drains of the transistors in the memory cells 205 of the string 220) that may conduct current under some operating conditions.

In some examples, multiple word lines 265 (e.g., in some cases all word lines 265) of the block 210—except a word line 265 associated with a page 215 of the memory cell 205 to be read—may concurrently be set to a voltage (e.g., VREAD) that is higher than the threshold voltage (VT) of the memory cells 205. VREAD may cause all memory cells 205 in the unselected pages 215 be activated so that each unselected memory cell 205 in the string 220 may maintain high conductivity within the channel. In some examples, the word line 265 associated with the memory cell 205 to be read may be set to a voltage, VTarget. Where the memory cells 205 are operated as SLC memory cells, VTarget may be a voltage that is between (i) VT of a memory cell 205 in an erased state and (ii) VT of a memory cell 205 in a programmed state.

When the memory cell 205 to be read exhibits an erased VT (e.g., VTarget>VT of the memory cell 205), the memory cell 205 may turn “ON” in response to the application of VTarget to the word line 265 of the selected page 215, which may allow a current to flow in the channel of the string 220, and thus from the bit line 250 to the source line 260. When the memory cell 205 to be read exhibits a programmed VT (e.g., VTarget<VT of the selected memory cell), the memory cell 205 may remain “OFF” despite the application of VTarget to the word line 265 of the selected page 215, and thus may prevent a current from flowing in the channel of the string 220, and thus from the bit line 250 to the source line 260.

A signal on the bit line 250 for the memory cell 205 (e.g., an amount of current below or above a threshold) may be sensed (e.g., by a sense component 170 as described with reference to FIG. 1), and may indicate whether the memory cell 205 became conductive or remained non-conductive in response to the application of VTarget to the word line 265 of the selected page 215. The sensed signal thus may be indicative of whether the memory cell 205 was in an erased state (e.g., storing a logic 1) or a programmed state (e.g., storing a logic 0). Though aspects of the example read operation above have been explained in the context of an SLC memory cell 205 for clarity, such techniques may be extended or altered and applied in the context of a multiple-level memory cell 205 (e.g., through the use of multiple values of VTarget corresponding to the different amounts of charge that may be stored in one multiple-level memory cell 205).

In some cases, as part of a program operation for a memory cell 205, charge may be added to a portion of the memory cell 205 such that current flow through the memory cell 205, and thus the corresponding string 220, may be inhibited when the memory cell 205 is later read. For example, charge may be injected into a charge trapping structure 120 as shown in memory cell 105-a of FIG. 1. In some cases, respective voltages may be applied to the word line 265 of the page 215 and the bulk of the memory cell 205 to be programmed such that a control gate 115 of the memory cell 205 is at a higher voltage than the bulk of the memory cell 205 (e.g., a positive voltage may be applied to the word line). Concurrently, voltages may be applied to the select line 235 and the select line 245 that are above the threshold voltages of the transistor 230 and the transistor 240, respectively, thereby activating the transistor 230 and the transistor 240, and the bit line 250 for the memory cell 205 to be programmed may be set to a relatively high voltage. This may cause an electric field such that electrons are pulled from the source of the memory cell 205 towards the drain. The electric field may also cause some of these electrons to be pulled through dielectric material 125 and thereby injected into the charge trapping structure 120 of the memory cell 205, through a process which may in some cases be referred to as tunnel injection.

In some cases, a single program operation may program some or all memory cells 205 in a page 215, as the memory cells 205 of the page 215 may all share a common word line 265 and a common bulk. For a memory cell 205 of the page 215 for which it is not desired to write a logic 0 (e.g., not desired to program the memory cell 205), the corresponding bit line 250 may be set to a relatively low voltage (e.g., ground), which may inhibit the injection of electrons into a charge trapping structure 120. Though aspects of the example program operation above have been explained in the context of an SLC memory cell 205 for clarity, such techniques may be extended and applied to the context of a multiple-level memory cell 205 (e.g., through the use of multiple programming voltages applied to the word line 265, or multiple passes or pulses of a programming voltage applied to the word line 265, corresponding to the different amounts of charge that may be stored in one multiple-level memory cell 205).

In some cases, as part of an erase operation for a memory cell 205, charge may be removed from a portion of the memory cell 205 such that current flow through the memory cell 205, and thus the corresponding string 220, may be uninhibited (e.g., allowed, at least to a greater extent) when the memory cell 205 is later read. For example, charge may be removed from a charge trapping structure 120 as shown in memory cell 105-a of FIG. 1. In some cases, respective voltages may be applied to the word line 265 of the page 215 and the bulk of the memory cell 205 to be erased such that a control gate 115 of the memory cell 205 is at a lower voltage than the bulk of the memory cell 205 (e.g., a positive voltage may be applied to the bulk), which may cause an electric field that pulls electrons out of the charge trapping structure 120 and into the bulk of the memory cell 205. In some cases, a single program operation may erase all memory cells 205 in a block 210, as the memory cells 205 of the block 210 may all share a common bulk.

To improve capacity of memory devices, the layers of the memory device may become smaller to allow for a larger quantity of word lines 265, for example. As the layers become smaller, however, the distance between word lines 265 may also decrease. This may make coupling (e.g., landing) a first conductive pillar of the memory device on a target word line 265 to couple the target word line 265 with circuitry (e.g., CMOS circuitry) of the memory device more difficult. For example, errors could occur during production of the memory device, and the first conductive pillar may fail to reach the target word line 265 or may couple the target word line 265 with other word lines 265. These errors may cause a shorting two or more word lines 265 of the memory device or create an open circuit at a word line 265, resulting in a defective memory device.

Accordingly, the disclosure provides architectures and manufacturing methods that may decrease the risk for word line short circuits or open circuits at a memory device. In accordance with examples as described herein, the memory device may include one or more rivets (e.g., rivet contacts, lateral word line contacts) that may couple a word line 265 with a conductive pillar that traverses a stack of materials of the memory device. The use of the rivet may allow for a conductive pillar to be coupled with a target word line 265 without requiring an end of the conductive pillar to be placed (e.g., landed) directly on the word line 265. Thus, the manufacturing methods described herein may ensure the conductive pillar is coupled with a target word line 265 and isolated from other word lines 265. Additionally, the architecture described herein may allow for the target word line 265 to be coupled with CMOS circuitry via a first conductive pillar without the use of a second conductive pillar, as the first conductive pillar may both traverse the stack of materials and be coupled with the CMOS circuitry. Therefore, total quantity of conductive pillars in the memory device may be reduced, and the risk of manufacturing errors may also be lowered.

FIG. 3A illustrates an example of a structure 300-a that supports NAND staircase landing pads conversion in accordance with examples as disclosed herein. The structure 300-a is a cross-sectional view of a stack of materials in a memory device that eventually form a plurality of conductive lines (e.g., word lines) separated a plurality of insulative material. The structure 300-a may be a structure formed during a manufacturing process for a memory device, such as memory device 100 as described with reference to FIG. 1. Additionally, the structure 300-a may adopt aspects of memory architecture 200 as described with reference to

FIG. 2.

A memory device may include a region in which a set of layers (e.g., conductive layers or word lines) of the memory device progressively decreases, forming a staircase structure. In some examples, the memory device may include one or multiple conductive pillars 355, which may couple one or more conductive layers (e.g., word lines) with circuitry 365 (e.g., CMOS circuitry) of the memory device. For example, a memory device may include a first conductive pillar 355, in which one end of the first conductive pillar 355 is in contact with a target word line, and another end of the first conductive pillar 355 is coupled with a second conductive pillar 355 that traverses a stack of materials of the memory device and couples to the circuitry 365.

To improve a capacity of the memory device, the set of layers of the memory device may become smaller to permit for a greater set of layers (e.g., word lines, memory cells, and other components). For example, as each layer gets thinner, the quantity of layers within a fixed vertical height may increase. As the set of layers become smaller, however, coupling (e.g., landing) the first conductive pillar 355 on a target word line may be more difficult. For example, errors could occur during production of the memory device, and the first conductive pillar 355 may fail to couple with the target word line, may couple with a non-targeted word line, or may couple the target word line with other word lines. These errors may cause a shorting two or more word lines of the memory device or form an open circuit at a word line, resulting in a defectiveness of the memory device.

Aspects described herein provide for a memory architecture and manufacturing method that decreases a risk for a word line short circuit or an open circuit at a memory device. The memory device may include one or more rivets 350 (e.g., rivet contacts, lateral word line contacts) that may couple a word line with a conductive pillar 355 that traverses a stack of materials of the memory device. The use of a rivet 350 may allow for a conductive pillar 355 to be coupled with a target word line without requiring an end of the conductive pillar 355 to be placed (e.g., landed) directly on the word line. That is, the rivet 350 may create a lateral connection of a conductive pillar 355 to a word line, which may avoid a placement of a conductive pillar 355 on a word line that may be more likely to result in manufacturing errors.

Additionally, the manufacturing method described herein may allow for coupling of a conductive pillar 355 with a target word line, while the conductive pillar 355 may be isolated from other word lines. The conductive pillar 355 may traverse a stack of materials of the memory device and be coupled with the circuitry 365. This allows for a word line to be coupled with the circuitry 365 without the use of multiple conductive pillars 355. Therefore, a total quantity of conductive pillars in the memory device may be reduced, and the risk of manufacturing errors may also be lowered.

The stack of materials may be formed by depositing multiple layers of materials. For example, the stack of materials may be formed by depositing interleaving layers of a first material and a second material (e.g., alternating layers of two materials). As illustrated in FIG. 3A, the stack of materials may include interleaving layers of an oxide material 305 and a nitride material 310. That is, an oxide material 305 may be placed (e.g., deposited) on top of a nitride material 310, and vice versa, to form each layer of the stack of materials. In some examples, the oxide material 305 may be a silicon oxide material, among other examples. Similarly, the nitride material 310 may be a silicon nitride material, among other examples. In some examples, the nitride material 310 may be a precursor to a conductive material which may form word lines of a completed memory device. For example, the nitride material 310 may be removed (e.g., etched) and replaced with a conductive material, as described in more detail herein, with reference to FIG. 3H. In some examples, the oxide material 305 may form a dielectric material in the memory device and may isolate word lines from each other.

The stack of materials may be modified to include one or more levels 315. For example, a portion of each of a subset of layers of the oxide material 305 and a subset of layers of the nitride material 310 may be removed to form a level 315-a, a level 315-b, a level 315-c, a level 315-d, and a level 315-e. In some examples, each level 315 may include one or more layers of materials. The levels 315, (e.g., and each layer of each level 315), may each be of a same height and width. For example, the level 315-b, the level 315-c, and the level 315-d may have a height equivalent to the height of two layers. Similarly, the level 315-a and the level 315-e may have a height equivalent to the height of four layers and the height of three layers, respectively. The widths of each level 315 may vary, as illustrated in FIG. 3A, so that the structure 300-a forms a staircase structure. Aspects of the disclosure may be implemented for different heights, widths, and quantities of levels 315, and the heights, widths, and quantities of levels 315 shown in FIG. 3A are for illustrative purposes. In some examples, the structure 300-a may represent a staircase region (e.g., of a 3D NAND memory device).

FIG. 3B illustrates an example of a structure 300-b that supports NAND staircase landing pads conversion in accordance with examples as disclosed herein. The structure 300-b may be a structure formed during a manufacturing process for a memory device, such as memory device 100 as described with reference to FIG. 1. For example, the structure 300-b may be a structure formed subsequent to the structure 300-a in the manufacturing process. Additionally, the structure 300-b may adopt aspects of memory architecture 200 as described with reference to FIG. 2.

The structure 300-b may have been processed to remove (e.g., etch) a top layer of each level 315. For example, an exposed portion of the oxide material 305 may have been removed from a layer of each of the of the level 315-b, the level 315-c, the level 315-d, and the level 315-e. This may result in exposing the nitride material 310 of each of the level 315-b, the level 315-c, the level 315-d, and the level 315-e. The oxide material 305 may be removed by recessing process, etching process, or by otherwise removing a portion of the oxide material 305 to expose the nitride material 310.

FIG. 3C illustrates an example of a structure 300-c that supports NAND staircase landing pads conversion in accordance with examples as disclosed herein. The structure 300-c may be a structure formed during a manufacturing process for a memory device, such as memory device 100 as described with reference to FIG. 1. For example, the structure 300-c may be a structure formed subsequent to the structure 300-b in the manufacturing process. Additionally, the structure 300-c may adopt aspects of the memory architecture 200 as described with reference to FIG. 2.

The structure 300-c may undergo a carbon doping process (e.g., a carbon implant process). The carbon doping may implant carbon into exposed nitride material 310 to form a carbon-doped nitride material 320. In some examples, the carbon-doped nitride material 320 may be a carbon-doped silicon nitride and may have different properties than the nitride material 310. In some examples, the carbon doping process may involve using a carbon gas (e.g., a gaseous carbon material) to implant carbon to the nitride material 305. For example, a carbon hydrate such as methane (CH₄) or ethane (C₂H₆). Additionally, or alternatively, the carbon doping may involve a pure carbon implant to the exposed nitride material 310. In some cases, the resulting concentration of carbon in the carbon-doped nitride material 320 after the carbon doping process may be in a range from 1×10¹⁸ to 5×10²¹ atoms of carbon per cubic centimeter of material.

In some examples, a liner material (e.g., an oxide liner) may be deposited over the structure 300-c. For example the liner material may be deposited after the caron doping process, and the liner material may cover a top portion of the caron-doped nitride material 320 and the oxide material 305, and sidewalls of the oxide material 305, the nitride material 310, and the carbon-doped nitride material 320. The liner material may be a thin layer of material and may be an example of a dielectric material (e.g., the oxide material 305). Depositing the liner material over the structure 300-c may provide isolation for word lines (e.g., sidewalls of the word lines) of the completed memory device, which may present word line short circuits.

FIG. 3D illustrates an example of a structure 300-d that supports NAND staircase landing pads conversion in accordance with examples as disclosed herein. The structure 300-d may be a structure formed during a manufacturing process for a memory device, such as memory device 100 as described with reference to FIG. 1. For example, the structure 300-d may be a structure formed subsequent to the structure 300-c in the manufacturing process. Additionally, the structure 300-d may adopt aspects of the memory architecture 200 as described with reference to FIG. 2.

The structure 300-d may be filled with a fill material 325. The fill material 325 may fill gaps above the staircase region relative to other portions of the structure. For example, a fill material 325 may be deposited on top of the layers to obtain a uniform height for the structure 300-d across the staircase region. In some examples, the fill material 325 may be an example of a dielectric material, such as an oxide material. In some examples, the fill material 325 may be deposited on top of the liner material (e.g., the oxide liner) if present.

FIG. 3E illustrates an example of a structure 300-e that supports NAND staircase landing pads conversion in accordance with examples as disclosed herein. The structure 300-e may be a structure formed during a manufacturing process for a memory device, such as memory device 100 as described with reference to FIG. 1. For example, the structure 300-e may be a structure formed subsequent to the structure 300-d in the manufacturing process. Additionally, the structure 300-e may adopt aspects of the memory architecture 200 as described with reference to FIG. 2.

In some examples, one or more pillar cavities 330 may be formed (e.g., etched) in the structure 300-e. For example, a portion of the stack of materials (e.g., including portions of layers and materials within the stack) may be removed to form a pillar cavity 330-a, a pillar cavity 330-b, a pillar cavity 330-c, and a pillar cavity 330-d. The pillar cavities 330 may be precursors for forming conductive pillars 355, and the pillar cavities may traverse the stack of materials and be perpendicular to the layers of the structure 300-e.

Forming the pillar cavity 330-a, the pillar cavity 330-b, the pillar cavity 330-c, and the pillar cavity 330-d may expose sidewalls of materials along the pillar cavities 330. For example, sidewalls of the oxide material 305, the nitride material 310, the carbon-doped nitride material 320, and the fill material 325 may be exposed along the pillar cavity 330-a, the pillar cavity 330-b, the pillar cavity 330-c, and the pillar cavity 330-d. In some examples, forming a pillar cavity 330 may result in at least a first sidewall of the nitride material 310 and a second sidewall of the nitride material 310. In some cases, the pillar cavities 330 may have a tapered shape. That is, the width of each pillar cavity 330 may vary along the length of the pillar cavity 330, as illustrated in FIG. 3E.

FIG. 3F illustrates an example of a structure 300-f that supports NAND staircase landing pads conversion in accordance with examples as disclosed herein. The structure 300-f may be a structure formed during a manufacturing process for a memory device, such as memory device 100 as described with reference to FIG. 1. For example, the structure 300-f may be a structure formed subsequent to the structure 300-e in the manufacturing process. Additionally, the structure 300-f may adopt aspects of the memory architecture 200 as described with reference to FIG. 2.

In some examples, the nitride material 310 may be recessed via the sidewalls of the nitride material 310 that were exposed by forming the pillar cavities 330, as described herein with reference to FIG. 3E. This may result in a portion of one or more layers of the nitride material 310 being removed. A selective etch chemistry (e.g., as part of a wet etch) may be used to remove layers of nitride material 310 that are not doped while layers of the nitride material that are doped are not removed. Following the removal of the portions of the one or more layers, a dielectric material 335 may be formed on the removed portions. The dielectric material 335 may be formed by depositing the dielectric material 335 along the sidewalls exposed by each of the pillar cavities 330. In some examples, the dielectric material 335 may be an example of an oxide material. In some examples, an etch-back procedure may be performed to reform the pillar cavity and remove any excess dielectric material 335 left in the pillar cavity.

In some examples, the carbon-doped nitride material 320 may be resistant to a removal process for recessing the sidewalls of the nitride material 310. Accordingly, the dielectric material 335 may replace the nitride material 310 along the pillar cavities 330, but the carbon-doped nitride material 320 may remain. The formed portions of the dielectric material 335 may result in isolating word lines of the completed memory device from conductive pillars 355 that may be formed along the pillar cavities 330. Meanwhile, the carbon-doped nitride material 320 may be replaced with conductive materials to form word lines, and each pillar cavity 330 may be formed into a conductive pillar 355 that is coupled with a respective word line (e.g., a target word line) based on forming the carbon-doped nitride material 320.

FIG. 3G illustrates an example of a structure 300-g that supports NAND staircase landing pads conversion in accordance with examples as disclosed herein. The structure 300-g may be a structure formed during a manufacturing process for a memory device, such as memory device 100 as described with reference to FIG. 1. For example, the structure 300-g may be a structure formed subsequent to the structure 300-f in the manufacturing process. Additionally, the structure 300-g may adopt aspects of the memory architecture 200 as described with reference to FIG. 2.

In some examples, the structure 300-g may undergo a metallization process (e.g., a replacement gate (RG) or replacement metal gate (RMG) process) to form a conductive material 340 in place of the nitride material 310. The metallization process may form (e.g., or partially form) the word lines for the completed memory device. In some examples, the conductive material 340 may be an example of a metal material (e.g., a tungsten material).

FIG. 3H illustrates an example of a structure 300-h that supports NAND staircase landing pads conversion in accordance with examples as disclosed herein. The structure 300-h may be a structure formed during a manufacturing process for a memory device, such as memory device 100 as described with reference to FIG. 1. For example, the structure 300-h may be a structure formed subsequent to the structure 300-g in the manufacturing process. Additionally, the structure 300-h may adopt aspects of the memory architecture 200 as described with reference to FIG. 2.

The carbon-doped nitride material 320 may be removed from the structure 300-h via the pillar cavity 330-a, the pillar cavity 330-b, the pillar cavity 330-c, and the pillar cavity 330-d to form a respective cavity 345. In some cases, the carbon-doped nitride material 320 may be removed by recessing the carbon-doped nitride material 320. In some cases, the removal process may be selective to the carbon-doped nitride material 320 (e.g., over the oxide material 305, the fill material 325, and the conductive material 340). Forming the cavity 345 may allow for formation of a portion of each word line and the rivet 350 to couple each word line to a conductive pillar 355.

In some cases, depending on the concentration of carbon of the carbon-doped nitride material 320, the carbon-doped nitride material 320 may not be explicitly removed (e.g., by recessing). Instead, the carbon-doped nitride material 320 may be removed during the formation (e.g., metallization) process of the rivets 350 and the conductive pillars 355, as described in FIG. 3I.

In some examples, one or more of the pillar cavities 330 may be used to form support vias (e.g., electrically inactive support vias), which may act as a support for the structure 300-h and the completed memory device. For example, the pillar cavities 330 may be filled with a non-conductive material (e.g., a carbon material), and may not be metallized or coupled with a word line. In these cases, the carbon-doped nitride material 320 may not be removed for sidewalls associated with the pillar cavities 330 that are to become support vias. This may be more cost and time efficient and may leave remnant carbon-doped nitride material 320 around support vias that may be detected in the completed memory device.

FIG. 3I illustrates an example of a structure 300-i that supports NAND staircase landing pads conversion in accordance with examples as disclosed herein. The structure 300-i may be a structure formed during a manufacturing process for a memory device, such as memory device 100 as described with reference to FIG. 1. For example, the structure 300-i may be a structure formed subsequent to the structure 300-h in the manufacturing process. Additionally, the structure 300-i may adopt aspects of memory architecture 200 as described herein, with reference to FIG. 2.

In the example of FIG. 3I, the formation of the rivets 350, the conductive pillars 355, and final portions of the word lines in the structure 300-I is illustrated. The formation may result in a conductive pillar 355-a, a conductive pillar 355-b, a conductive pillar 355-c, and a conductive pillar 355-d, each associated with a respective rivet 350. Each conductive pillar 355 may be coupled with a respective word line of the structure 300-i via the respective rivets 350. A rivet 350 may refer to the conductive material that couples the conductive pillar 355 with its respective access line. In some examples, the rivet 350 may refer to the conductive material that occupies the space vacated by the carbon-doped nitride material 320. In some examples, the rivet 350 may refer to the conductive material that occupies same level as the respective access line. In some examples, the rivet 350 may refer to any combination of conductive material that is configured to establish an electrical coupling between the conductive pillar 355 and its respective access line. The rivet 350 and the conductive pillar 355 may be formed using the same deposition process.

In some examples, the formation may involve depositing a first material (e.g., a carbon material, or another material), and performing a subsequent metallization process. For example, a sacrificial material (e.g., a carbon material or a carbon nitride material) may be deposited in each pillar cavity 330. In some cases, the pillar cavities 330 may be selectively masked. For example, pillar cavities 330 filled with sacrificial material that are intended as support vias may be masked to avoid metallization of the support vias. Then, unmasked pillar cavities 330 filled with sacrificial material, such as the pillar cavity 330-a, the pillar cavity 330-b, the pillar cavity 330-c, and the pillar cavity 330-d, may undergo metallization to form the conductive pillar 355-a, the conductive pillar 355-b, the conductive pillar 355-c, and the conductive pillar 355-d.

In some examples, the conductive pillar 355-a, the conductive pillar 355-b, the conductive pillar 355-c, and the conductive pillar 355-d may each be coupled with respective connections 360. The connections 360 may couple the respective conductive pillars 355 to circuitry 365 of the memory device, such as CMOS circuitry.

Accordingly, the manufacturing methods described herein, with reference to FIGS. 3A-3I, may allow for formation of the staircase structure of a memory device in which a word line is coupled with a conductive pillar 355 via a rivet 350, while the conductive pillar 355 is isolated from other word lines. Each conductive pillar 355 may traverse the stack of materials of the memory device and be coupled with circuitry 365, and each conductive pillar 355 may travel in a direction perpendicular to the word lines. The memory device may be operable to couple the word line to the circuitry 365 via the rivet 350, the conductive pillar 355, and the connections 360. This would allow for a word line to be coupled with the circuitry 365 without the use of multiple conductive pillars 355. Therefore, a total quantity of conductive pillars in the memory device may be reduced, and the risk of manufacturing errors may also be lowered by using the rivet 350 to couple a conductive pillar 355 to a word line. One end of the word line may be coupled with a conductive pillar 355 while a different end of the word line (not shown) may be coupled with NAND channel and may form a NAND memory cell.

FIG. 4 illustrates a flowchart showing a method 400 that supports NAND staircase landing pads conversion in accordance with examples as disclosed herein. The operations of method 400 may be implemented by a manufacturing system or its components as described herein. For example, the operations of method 400 may be performed by a manufacturing system as described with reference to FIGS. 1 through 3I. In some examples, a manufacturing system may execute a set of instructions to control the functional elements of the device to perform the described functions. Additionally, or alternatively, the manufacturing system may perform aspects of the described functions using special-purpose hardware.

At 405, the method may include forming a stack including a set of layers, the set of layers including a set of oxide layers and a set of nitride layers, where the stack includes a set of levels, each level of the set of levels including the set of layers. The operations of 405 may be performed in accordance with examples as disclosed herein.

At 410, the method may include removing a portion of the set of layers to form each level of the set of levels, where the portion includes a first subset of the set of oxide layers and a first subset of the set of nitride layers. The operations of 410 may be performed in accordance with examples as disclosed herein.

At 415, the method may include doping at least one nitride layer of each of one or more levels of the set of levels with a carbon material to form a carbon-doped layer. The operations of 415 may be performed in accordance with examples as disclosed herein.

At 420, the method may include forming a lateral word line contact that couples a first word line with a conductive pillar based at least in part on the doping. The operations of 420 may be performed in accordance with examples as disclosed herein.

In some examples, an apparatus as described herein may perform a method or methods, such as the method 400. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for forming a stack comprising a set of layers, the set of layers comprising a set of oxide layers and a set of nitride layers, wherein the stack comprises a set of levels, each level of the set of levels comprising the set of layers; removing a portion of the set of layers to form each level of the set of levels, wherein the portion comprises a first subset of the set of oxide layers and a first subset of the set of nitride layers; doping at least one nitride layer of each of one or more levels of the set of levels with a carbon material to form a carbon-doped layer; and forming a lateral word line contact that couples a first word line with a conductive pillar based at least in part on the doping.

Aspect 2: The method, apparatus, or non-transitory computer-readable medium of aspect 1, further comprising: depositing an oxide layer over the at least one nitride layer of the one or more levels of the set of levels.

Aspect 3: The method, apparatus, or non-transitory computer-readable medium of any of aspects 1 through 2, further comprising: removing a portion of the stack to form a pillar cavity comprising a first sidewall and a second sidewall.

Aspect 4: The method, apparatus, or non-transitory computer-readable medium of aspect 3, further comprising: removing a portion of one or more nitride layers of the set of nitride layers based at least in part on removing the portion of the stack; and depositing an oxide layer on the first sidewall and the second sidewall, wherein forming the lateral word line contact is based at least in part on depositing the oxide layer.

Aspect 5: The method, apparatus, or non-transitory computer-readable medium of aspect 4, further comprising: removing, based at least in part on depositing the oxide layer, a portion of the carbon-doped layer associated with the first word line to form a cavity associated with the lateral word line contact.

Aspect 6: The method, apparatus, or non-transitory computer-readable medium of aspect 5, wherein forming the lateral word line contact further comprises: depositing a conductive material in the pillar cavity and the cavity to form the conductive pillar and the lateral word line contact, wherein the lateral word line contact is coupled with the first word line is based at least in part on depositing the conductive material.

Aspect 7: The method, apparatus, or non-transitory computer-readable medium of any of aspects 5 through 6, wherein the portion of the carbon-doped layer is selectively removed based at least in part on the doping.

Aspect 8: The method, apparatus, or non-transitory computer-readable medium of any of aspects 1 through 7, wherein forming the stack comprises: depositing each of a nitride layer of the set of nitride layers on each of an oxide layer of the set of oxide layers to form the stack comprising the set of oxide layers interleaving the set of nitride layers.

Aspect 9: The method, apparatus, or non-transitory computer-readable medium of any of aspects 1 through 8, further comprising: removing at least one oxide layer form each of one or more levels of the set of levels based at least in part on removing the portion of the set of layers, wherein doping the at least one nitride layer of each of the one or more levels of the set of levels with the carbon material is based at least in part on removing the at least one oxide layer form each of one or more levels of the set of levels.

Aspect 10: The method, apparatus, or non-transitory computer-readable medium of any of aspects 1 through 9, wherein the carbon material comprises a gaseous carbon material.

Aspect 11: The method, apparatus, or non-transitory computer-readable medium of any of aspects 1 through 10, wherein each level of the set of levels comprises a respective height and a respective width.

An apparatus is described. The following provides an overview of aspects of the apparatus as described herein:

Aspect 12: An apparatus, including: a stack of materials including a plurality of word lines; a lateral word line contact that couples a first word line of the plurality of word lines with a conductive pillar; a carbon-doped material in contact with the first word line; and a first insulating material insulating the conductive pillar from a second word line of the plurality of word lines.

Aspect 13: The apparatus of aspect 12, where the conductive pillar traverses the stack of materials and is perpendicular to the first word line.

Aspect 14: The apparatus of any of aspects 12 through 13, where a metal oxide semiconductor is positioned below the stack of materials, the conductive pillar is coupled with the metal oxide semiconductor.

Aspect 15: The apparatus of aspect 14, where: a plurality of lateral word line contacts coupling a respective word line of the plurality of word lines with a respective conductive pillar of a plurality of conductive pillars, the plurality of conductive pillars coupled with the metal oxide semiconductor.

Aspect 16: The apparatus of aspect 15, where one or more portions of the first word line include a second insulating material and the plurality of conductive pillars are isolated from the first word line based at least in part on the second insulating material.

Aspect 17: The apparatus of any of aspects 12 through 16, further including: a plurality of support vias electrically isolated from the plurality of word lines.

Aspect 18: The apparatus of aspect 17, where a portion of a first layer of the stack of materials includes the carbon-doped material, the portion of the first layer being in contact with a first support via of the plurality of support vias.

Another apparatus is described. The following provides an overview of aspects of the apparatus as described herein:

Aspect 19: An apparatus, including: a stack of materials including a plurality of word lines; a plurality of lateral word line contacts that couples a respective word line of the plurality of word lines with a respective conductive pillar of a plurality of conductive pillars; a carbon-doped material in contact with the plurality of word lines; and a metal oxide semiconductor positioned below the stack of materials and coupled with each respective conductive pillar.

Aspect 20: The apparatus of aspect 19, where one or more portions of a first word line of the plurality of word lines include an insulating material and the first word line is isolated from one or more conductive pillars of the plurality of conductive pillars based at least in part on the insulating material.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials, or combinations thereof. In some examples, one layer or level may be composed of two or more sublayers or sublevels.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over, as one or more instructions or code, a computer-readable medium. Other examples and implementations are within the scope of the disclosure and appended claims. For example, due to the nature of software, described functions can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and components described in connection with the disclosure herein may be implemented or performed with a general-purpose processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method, comprising:
forming a stack comprising a set of layers, the set of layers comprising a set of oxide layers and a set of nitride layers, wherein the stack comprises a set of levels, each level of the set of levels comprising the set of layers;
removing a portion of the set of layers to form each level of the set of levels, wherein the portion comprises a first subset of the set of oxide layers and a first subset of the set of nitride layers;
doping at least one nitride layer of each of one or more levels of the set of levels with a carbon material to form a carbon-doped layer; and
forming a lateral word line contact that couples a first word line with a conductive pillar based at least in part on the doping.

2. The method of claim 1, further comprising:
depositing an oxide layer over the at least one nitride layer of the one or more levels of the set of levels.

3. The method of claim 1, further comprising:
removing a portion of the stack to form a pillar cavity comprising a first sidewall and a second sidewall.

4. The method of claim 3, further comprising:
removing a portion of one or more nitride layers of the set of nitride layers based at least in part on removing the portion of the stack; and
depositing an oxide layer on the first sidewall and the second sidewall, wherein forming the lateral word line contact is based at least in part on depositing the oxide layer.

5. The method of claim 4, further comprising:
removing, based at least in part on depositing the oxide layer, a portion of the carbon-doped layer associated with the first word line to form a cavity associated with the lateral word line contact.

6. The method of claim 5, wherein forming the lateral word line contact further comprises:
depositing a conductive material in the pillar cavity and the cavity to form the conductive pillar and the lateral word line contact, wherein the lateral word line contact is coupled with the first word line is based at least in part on depositing the conductive material.

7. The method of claim 5, wherein the portion of the carbon-doped layer is selectively removed based at least in part on the doping.

8. The method of claim 1, wherein forming the stack comprises:
depositing each of a nitride layer of the set of nitride layers on each of an oxide layer of the set of oxide layers to form the stack comprising the set of oxide layers interleaving the set of nitride layers.

9. The method of claim 1, further comprising:
removing at least one oxide layer form each of one or more levels of the set of levels based at least in part on removing the portion of the set of layers, wherein doping the at least one nitride layer of each of the one or more levels of the set of levels with the carbon material is based at least in part on removing the at least one oxide layer form each of one or more levels of the set of levels.

10. The method of claim 1, wherein the carbon material comprises a gaseous carbon material.

11. The method of claim 1, wherein each level of the set of levels comprises a respective height and a respective width.

12. An apparatus, comprising:
a stack of materials comprising a plurality of word lines;
a lateral word line contact that couples a first word line of the plurality of word lines with a conductive pillar;
a carbon-doped material in contact with the first word line; and
a first insulating material insulating the conductive pillar from a second word line of the plurality of word lines.

13. The apparatus of claim 12, wherein the conductive pillar traverses the stack of materials and is perpendicular to the first word line.

14. The apparatus of claim 12, wherein:
a metal oxide semiconductor is positioned below the stack of materials, and
the conductive pillar is coupled with the metal oxide semiconductor.

15. The apparatus of claim 14, wherein:
a plurality of lateral word line contacts coupling a respective word line of the plurality of word lines with a respective conductive pillar of a plurality of conductive pillars, the plurality of conductive pillars coupled with the metal oxide semiconductor.

16. The apparatus of claim 15, wherein one or more portions of the first word line comprise a second insulating material and the plurality of conductive pillars are isolated from the first word line based at least in part on the second insulating material.

17. The apparatus of claim 12, further comprising:
a plurality of support vias electrically isolated from the plurality of word lines.

18. The apparatus of claim 17, wherein a portion of a first layer of the stack of materials comprises the carbon-doped material, the portion of the first layer being in contact with a first support via of the plurality of support vias.

19. An apparatus, comprising:
a stack of materials comprising a plurality of word lines;
a plurality of lateral word line contacts that couples a respective word line of the plurality of word lines with a respective conductive pillar of a plurality of conductive pillars;
a carbon-doped material in contact with the plurality of word lines; and
a metal oxide semiconductor positioned below the stack of materials and coupled with each respective conductive pillar.

20. The apparatus of claim 19, wherein one or more portions of a first word line of the plurality of word lines comprise an insulating material and the first word line is isolated from one or more conductive pillars of the plurality of conductive pillars based at least in part on the insulating material.
